(19) United States
(12) Patent Application Publication
(10) Pub. No.: US 2019/0280679 A1
(43) Pub. Date: Sep. 12, 2019

(54) Rise and Fall Time Mismatch Adjustment Circuit for USB-On-The-Go Modules

(71) Applicant: Microchip Technology Incorporated, Chandler, AZ (US)

(72) Inventors: Ganesan Iyer, Bangalore (IN); Cristian Albina, Chandler, AZ (US); Jaswant Singh Rajpurohit, Bangalore (IN)

(73) Assignee: Microchip Technology Incorporated, Chandler, AZ (US)

(21) Appl. No.: 15/915,484

(22) Filed: Mar. 8, 2018

(51) Int. Cl. H03K 5/01; H03K 5/12; H01R 13/66; G06F 13/42

(52) U.S. Cl. CPC H03K 5/01; H03K 5/12; H01R 24/60; G06F 13/4282; H01R 13/665

(57) ABSTRACT

An apparatus may include an output pin, an output driver circuit communicatively coupled to the output pin and configured to output a rising signal or falling signal on the output pin, and a programmable current source communicatively coupled to the output driver circuit. The programmable current source may be configured to drive a speed of a rising signal or of a falling signal on the output pin and, based upon adjustment data, increase or decrease current to the output driver circuit to change the speed of the rising signal or of the falling signal on the output pin.

### FIELD OF THE INVENTION

The present disclosure relates to serial communications and, more particularly, to rise and fall time mismatch adjustment circuit for universal serial bus (USB) on-the-go (OTG) modules.

### BACKGROUND

A physical USB connector or interface may include four shielded wires terminated by pins. Pin 1, which is the VBUS, is used to power any connected peripheral by supplying a voltage such as a +5V voltage from the USB host. Pin 2 is the negative data terminal denoted as D− (DM), while Pin 3 is the positive data terminal denoted as D+ (DP). Pin 4 is the ground connection (GND).

USB OTG enables a USB host—such as a head unit, computer, or other suitable electronic device—to allow other USB devices—such as USB flash drives, digital cameras, mice or keyboards—to be attached to them. Use of USB OTG allows those devices to switch back and forth between the roles of host and device. For instance, a mobile phone may read from removable media as the host device, but present itself as a USB Mass Storage Device when connected to a host computer. USB OTG allows a USB element to perform both master and slave roles. Whenever two USB devices are connected and one of them is a USB OTG device, they establish a communication link. The device controlling the link is called the master or host, while the other is called the slave or peripheral.

USB OTG defines two roles for devices: OTG A-device and OTG B-device, specifying which side supplies power to the link, and which initially is the host. The OTG A-device is a power supplier, and an OTG B-device is a power consumer. In the default link configuration, the A-device acts as a USB host with the B-device acting as a USB peripheral. The host and peripheral modes may be exchanged later by using a host negotiation protocol (HNP). The initial role of each device is defined by which mini plug a user inserts into its receptacle/

Standard USB uses a master/slave architecture; a host acts as the master device for the entire bus, and a USB device acts as a slave. If implementing standard USB, devices must assume one role or the other, with computers generally set up as hosts, while (for example) printers normally function as slaves. In the absence of USB OTG, cell phones often implemented slave functionality to allow easy transfer of data to and from computers. Such phones, as slaves, could not readily be connected to printers as they also implemented the slave role.

When a device is plugged into the USB bus, the master device, or host, sets up communications with the device and handles service provisioning (the host's software enables or does the needed data-handling such as file managing or other desired kind of data communication or function). That allows the devices to be greatly simplified compared to the host; for example, a mouse contains very little logic and relies on the host to do almost all of the work. The host controls all data transfers over the bus, with the devices capable only of signaling (when polled) that they require attention. To transfer data between two devices, for example from a phone to a printer, the host first reads the data from one device, then writes it to the other.

While the master-slave arrangement works for some devices, many devices can act either as master or as slave depending on what else shares the bus. For instance, a computer printer is normally a slave device, but when a USB flash drive containing images is plugged into the printer's USB port with no computer present (or at least turned off), it would be useful for the printer to take on the role of host, allowing it to communicate with the flash drive directly and to print images from it.

USB OTG recognizes that a device can perform both master and slave roles, and so subtly changes the terminology. With OTG, a device can be either a host when acting as a link master, or a “peripheral” when acting as a link slave. The choice between host and peripheral roles is handled entirely by which end of the cable the device is connected to. The device connected to the “A” end of the cable at start-up, known as the “A-device”, acts as the default host, while the “B” end acts as the default peripheral, known as the “B-device”.

After initial startup, setup for the bus operates as it does with the normal USB standard, with the A-device setting up the B-device and managing all communications. However, when the same A-device is plugged into another USB system or a dedicated host becomes available, it can become a slave.

### SUMMARY

Embodiments of the present disclosure include an apparatus. The apparatus may include a first output pin, a first output driver circuit communicatively coupled to the first output pin and configured to output a rising signal or falling signal on the first output pin, and a first programmable current source communicatively coupled to the first output driver circuit. The first programmable current source may be configured to drive a speed of a rising signal or of a falling signal on the first output pin and, based upon first adjustment data, increase or decrease current to the first output driver circuit to change the speed of the rising signal or of the falling signal on the first output pin. In combination with any of the above embodiments, the apparatus may further include a second output pin, a second output driver circuit communicatively coupled to the second output pin and configured to output a rising signal or falling signal on the second output pin, and a second programmable current source communicatively coupled to the second output driver circuit. The second programmable current source may be configured to drive a speed of a rising signal or of a falling signal on the second output pin, and, based upon second adjustment data, increase or decrease current to the second output driver circuit to change the speed of the rising signal or of the falling signal on the second output pin. In combination with any of the above embodiments, the first output pin may be a DM pin of a USB connection. In combination with any of the above embodiments, the second output pin may be a DP pin of the USB connection. In combination with any of the above embodiments, the second programmable current source may be communicatively coupled to the first output driver circuit and configured to drive a speed of the rising signal on the first output pin and, based upon second adjustment data, increase or decrease current to the first output driver circuit to change a speed of the rising signal. In combination with any of the above embodiments, the first programmable current source may be further configured to drive the speed of the falling signal on the first output pin. In combination with any of the above embodiments, the first programmable current source may be configured to use the first adjustment data to increase or decrease current to the first output driver circuit in order to more closely match a speed of a rising signal or of a falling signal on a second output pin. In combination with any of the above embodiments, the first adjustment data may include information of a relative increase or decrease of the speed of a rising signal or of a falling signal. In combination with any of the above embodiments, the first programmable current source may be configured to increase or decrease current to the first output driver circuit to change the speed of the rising signal or of the falling signal on the first output pin in response to a change in a load on the first output pin.

Embodiments of the present disclosure may include a system with a first output pin, a second output pin, a first output driver circuit communicatively coupled to the first output pin and configured to output a rising signal or falling signal on the first output pin, and a first programmable current source communicatively coupled to the first output driver circuit. The first programmable current source may be configured to drive a speed of a rising signal or of a falling signal on the first output pin and, based upon first adjustment data, increase or decrease current to the first output driver circuit to change the speed of the rising signal or of the falling signal on the first output pin. In combination with any of the above embodiments, the system may include a second output driver circuit communicatively coupled to the second output pin and configured to output a rising signal or falling signal on the second output pin and a second programmable current source communicatively coupled to the second output driver circuit. The second programmable current source may be configured to drive a speed of a rising signal or of a falling signal on the second output pin and, based upon second adjustment data, increase or decrease current to the second output driver circuit to change the speed of the rising signal or of the falling signal on the second output pin. In combination with any of the above embodiments, the first output pin is a DM pin of a USB connection and the second output pin is a DP pin of the USB connection. In combination with any of the above embodiments, the second programmable current source may be communicatively coupled to the first output driver circuit and configured to drive a speed of the rising signal on the first output pin and, based upon second adjustment data, increase or decrease current to the first output driver circuit to change a speed of the rising signal. In combination with any of the above embodiments, the first programmable current source may be further configured to drive the speed of the falling signal on the first output pin. In combination with any of the above embodiments, the first programmable current source may be configured to use the first adjustment data to increase or decrease current to the first output driver circuit in order to more closely match a speed of a rising signal or of a falling signal on the second output pin. In combination with any of the above embodiments, the first adjustment data includes information of a relative increase or decrease of the speed of a rising signal or of a falling signal. In combination with any of the above embodiments, the first programmable current source may be configured to increase or decrease current to the first output driver circuit to change the speed of the rising signal or of the falling signal on the first output pin in response to a change in a load on the first output pin.

Embodiments of the present disclosure may include USB hosts, USB hubs, USB master devices, USB controllers, or electronic devices including any of the apparatuses or systems of the above embodiments.

Embodiments of the present disclosure may include methods performed by any of the embodiments of apparatuses, systems, USB hosts, USB hubs, USB master devices, USB controllers, or electronic devices described above.

### BRIEF DESCRIPTION OF THE DRAWINGS

FIG. 1 is an illustration of a circuit configured to perform mismatch adjustment, according to embodiments of the present disclosure.

FIG. 2 is an illustration of a circuit for implementing control of pins for a USB connection, according to embodiments of the present disclosure.

FIGS. 3A and 3B are a more detailed schematic of a circuit configured to perform mismatch adjustment, according to embodiments of the present disclosure.

FIGS. 4A and 4B are an illustration of another, more detailed schematic of a circuit configured to perform mismatch adjustment, according to embodiments of the present disclosure.

### DETAILED DESCRIPTION

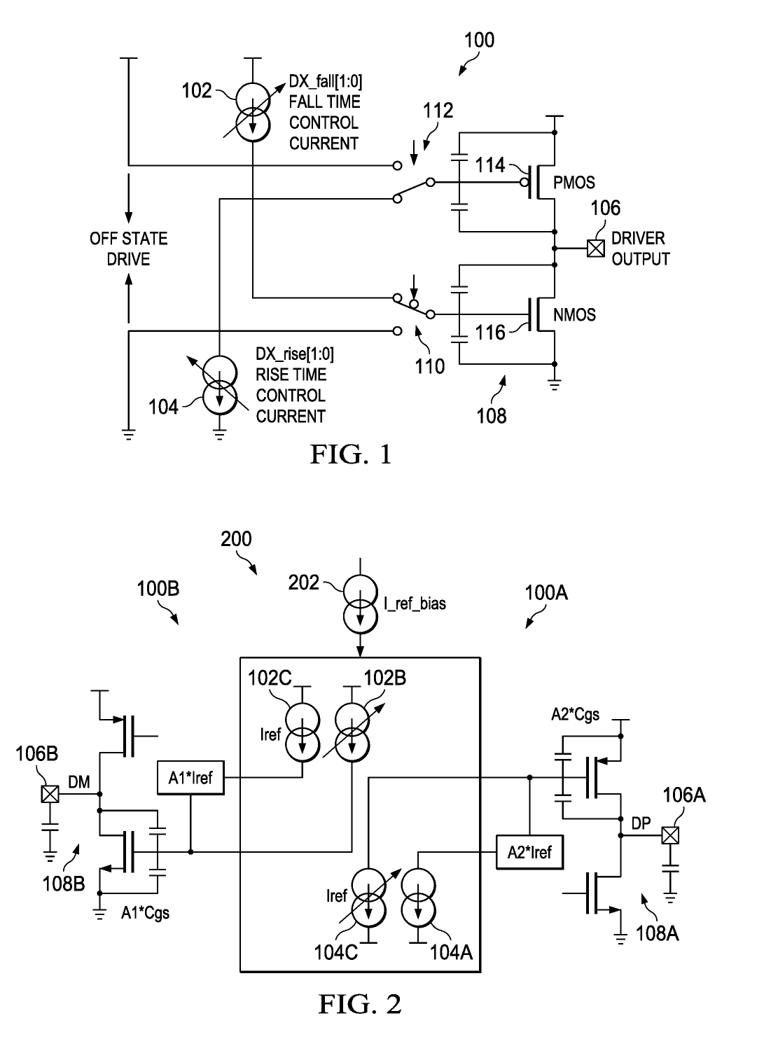

FIG. 1 is an illustration of a circuit 100 configured to perform mismatch adjustment, according to embodiments of the present disclosure. In one embodiment, circuit 100 may be configured to perform mismatch adjustment for rise and fall times on pins, connector, or other interfaces. In another embodiment, circuit 100 may be configured to perform mismatch adjustment for USB modules, circuits, devices, elements, pins, packages, or other entities. In yet another embodiment, circuit 100 may be configured to perform mismatch adjustment for USB OTG entities.

Circuit 100 may be applied for respective DP and DM pins on a given USB connection. Accordingly, multiple instances of circuit 100 may be included within a given USB entity. For example, an instance of circuit 100 may be used for each of the respective DP and DM pins on a USB connection, resulting in at least two instances of circuit 100 for a USB connection.

Circuit 100 may include a pin 106. Pin 106 may implement an instance of a DP or an instance of a DM, depending upon the use of circuit 100. Circuit 100 may include an output driver 108. Output driver 108 may be implemented in any suitable manner, such as by the serial or cascade connection of a PMOS and an NMOS transistor. Output driver 108 may include capacitors between the gate, source, and drain pins of the transistors. The capacitors may be a symbolic representation of the intrinsic capacitance of the transistors, rather than physical capacitors placed within circuit 100. The capacitance may be a relatively large value due to the large size of the MOS device. Pin 106 may be coupled to the intersection of the transistors in output driver 108. Circuit 100 may also be configured to implement programable line termination for both low and high-speed host applications and tri-state capability. The configuration of circuit 100 for low-speed or high-speed operation may be determined by a unit current, shown below current bias source (I_ref_bias) 202 in FIG. 2. Current bias source 202 may be reduced by a certain factor to reduce or increase the rise and fall time.

In one embodiment, circuit 100 may be configured to drive the rise time and fall time of voltages or signals on pin 106 through a fall time current control circuit (FTCCC) 102 communicatively coupled to driver 108. FTCCC 102 may be connected to driver 108 through a gate of the NMOS component 116 of driver 108. The signal may be appropriately switched by a switch 110 depending upon the mode of operation of circuit 100. Switch 110 may be configured to connect the gate of the NMOS 116 of driver 108 to either FTCCC 102 to or to ground. Switch 110 may be configured to connect the gate of the NMOS 116 of driver 108 to FTCCC 102 to turn on the NMOS 116. Switch 110 may be configured to connect the gate of the NMOS 116 of driver 108 to ground to turn off the NMOS 116.

In another embodiment, circuit 100 may be configured to drive the rise time and fall time of voltages or signals on pin 106 through a rise time current control circuit (RTCCC) 104 communicatively coupled to driver 108. RTCCC 104 may be connected to driver 108 through a gate of the PMOS component 114 of driver 108. The signal may be appropriately switched by a switch 112 depending upon the mode of operation of circuit 100. Switch 112 may be configured to connect the gate of the PMOS 114 of driver 108 to either RTCCC 104 to or to VDD. Switch 112 may be configured to connect the gate of the PMOS 114 to VDD to turn the PMOS 114 off. Switch 112 may be configured to connect the gate of the PMOS 114 to RTCCC 104 to turn the PMOS 114 on.

The signal controlling switch 112 and switch 110 may be configured to apply respective ones of RTCCC 104/FTCCC 102 and VDD to the gates of the respective MOS elements of driver 108. If switch 110 is connected to VDD, switch 112 may be connected to RTCCC 104. If switch 112 is connected to VDD, switch 110 may be connected to FTCCC 102. When driver 108 is to be shut off, both switch 110 and switch 112 may be connected to VDD.

FTCCC 102 and RTCCC 104 may be implemented in any suitable manner. In one embodiment, FTCCC 102 and RTCCC 104 may be implemented as programmable current sources. In another embodiment, FTCCC 102 and RTCCC 104 may include any suitable range or resolution for adjustment of current produced therefrom.

Circuit 100, or a system in which circuit 100 is implemented, may include any suitable mechanism for issuing control or adjustment commands, signals, or instructions to FTCCC 102 and RTCCC 104. Such signals may include signals for defining an output level, an adjustment to an output level (positive or negative), or a signal specifying any of these in absolute or relative terms. In one embodiment, FTCCC 102 and RTCCC 104 may include trimming bits to adjust the respective current output up or down. In a further embodiment, the trimming bits may specify a code, the value of which may represent a percentage by which the output current should be adjusted. In yet a further embodiment, the mapping of a code to a percentage adjustment might not be linear.

For example, FTCCC 102 and RTCCC 104 may include two trimming bits, though any suitable number of bits may be used. The trimming bits, given as [1:0], may thus allow representation of four adjustment levels. In one embodiment, the four adjustment levels may be linearly spaced between each other. In another embodiment, the four adjustment levels might not be linearly spaced between each other.

In one embodiment, FTCCC 102 and RTCCC 104 may be independently adjusted from one another. FTCCC 102 and RTCCC 104 might retain their own separate trimming bits. However, the separate trimming bits for FTCCC 102 and RTCCC 104 might be stored together or adjacently. The trimming bits for FTCCC 102 and RTCCC 104 might be stored together with other information, such that the combined four bits are together a word or part of a word stored in, for example, a configuration register. As multiple pins may be needed to implement a USB connection, such as a DM and a DP pin, multiple instances of circuit 100 may exist and thus multiple instances of the separate trimming bits for instances of FTCCC 102 and RTCCC 104. Each of these trimming bit pairs may be independently controlled. The various pairs of bits may be collected in an amalgamation and controlled, for example, in a single command, instruction, register value, or other instruction or control signal from a system, microcontroller, or other electronic device that is utilizing circuit 100.

In one embodiment, for a given USB connection with a DP pin and a DM pin (and thus two instances of circuit 100 and pin 106), two trimming bits may be provided to individually adjust the falling edge of the DP pin (DP_fall); two trimming bits to adjust the rising edge of the DP pin (DP_rise); two trimming bits to adjust the falling edge of the DM pin (DM_fall); and two trimming bits to adjust the rising edge of the DM pin (DP_rise). Thus, the USB connection rising and falling adjustment may be specified by a total of eight programmable bits. These may be specified, for example, in a configuration register, an electronic fuse, or other suitable mechanisms. Setting of the specification may be made by a command, instruction, or other signal.

In one embodiment, the values of the output level that are adjusted by the trimming bits may be specified according to a value of the output current of a respective one of FTCCC 102 and RTCCC 104. In another embodiment, the values of the output level that are adjusted by the trimming bits may be specified according to the effect of the output current on a respective one of FTCCC 102 and RTCCC 104. For example, a trimming bit code of “10” might be used to increase current of FTCCC 102 by a specified percentage. However, in other implementations the trimming bit code of “10” might be used to increase current of FTCCC 102 sufficient to change the rise time of the output on pin 106 by a specified percentage.

In one embodiment, FTCCC 102 and RTCCC 104 may be implemented as programmable current sources that are centered on the [00] trim bit which can be adjusted in both directions for faster or slower rise and fall times across pin 106.

The standards promulgated by USB specifications include rise (Tr) and fall (Tf) times of the DM and DP pins. Various USB devices may be designed to meet these specifications by being designed to match tolerances of transistors and other elements within the USB device. Such designs are often made using simulations of theoretical models However, in various USB devices, the final module implementation as physically produced may yield variances in area or power consumption. Furthermore, computer or theoretical models used during design may have been inaccurate. This may cause the USB device to fail to meet USB specifications. Even if a circuit implementing an internal part of a USB device meets all requirements through successful implementation of symmetrical layout, analog matching rules, or reduced parasitics, other portions external to the circuit—such as the bonding, package, application board, and the load to the drivers—may cause a mismatch in the rise and fall times of the DM and DP pins.

Embodiments of the present disclosure may be used to apply a mismatch parameter for rise and fall times. The parameter may be used to center rise and fall times of the DM and DP pins. The adjustments may be used to compensate for inaccurate transistor models, mismatch of the device load to which the user will connect the USB cable, or other sources of variances in rise and fall times.

In one embodiment, the rise and fall time across a given pin may be individually varied by +15% to −5%. This range may be available for both DP and DM pins. The adjustment may be defined according to the trim bits. These adjustments may also be used in case the slope of the rise or fall time has to be made slower to avoid quiescent current during switching and then have an impact on electromagnetic characteristics of the USB device. The adjustment may be performed after manufacture and during product test. In such a case, the adjustment might be made once and set permanently or semi-permanently such that the adjustment is available to fuse with the USB device. Such an adjustment may be set by values, for example, in an electronic fuse ore register. In another embodiment, the adjustment might be made upon a detection of a rise or fall time that is out of specification. Such an adjustment may be made after detecting the change due to environmental changes or a new load attached to the USB device. In such embodiments, the adjustment may be made dynamically. These adjustments may be made by software in a microcontroller or a system in which the control circuit resides.

As discussed above, embodiments of the present disclosure add control capability of the bias current to charge and discharge the (effective) gate capacitor of output driver 108. The control over the bias current implemented by using two trim bits may be described by four targeted parameters Trdp, Tfdp, Trdm, Tfdm. Driver 108 may be turned on or off by charging or discharging the gate oxide of its transistors. Thus, by controlling charge or discharge rate of the gate oxide the slew for rise or fall could be modified.

The following table illustrates example trimming bit values and corresponding rise and fall time adjustments.

TABLE 1

Adjustment

| BIT CODE <1:0> | dm_fall | dm_rise | dp_fall | dp_rise |
|---|---|---|---|---|
| 00 | 0% | 0% | 0% | 0% |
| 01 | +10% | −5% | +10% | −5% |
| 10 | −5% | −10% | −5% | −10% |
| 11 | +5% | +10% | +5% | +10% |

Thus, a “00” code may represent no change for the output. Each of these adjustments may be made with a tolerance of 20% of the percentages represented therein. USB specifications may require that the rise time and the fall time should generally match. In particular, the rise time and fall time must be within 10% of each other. The rise time and the fall time may themselves be between a range of 5 ns to 20 ns. Thus, for example, if rise time for the DM pin is 10 ns, the fall time for the DM pin must be between 9-11 ns. If the fall time is beyond this range, the circuit might be outside the USB specification requirements. Embodiments of the present disclosure may, given a detection that the fall time is 9 ns, adjust the fall time to be 10% faster. Consequently, the rise time (10 ns) and the fall time (9.9 ns) may more closely match. Furthermore, the fall time could be adjusted to be 5% faster and the rise time could be adjusted to be 5% slower. In addition, the rise time could be adjusted to be 10% slower.

Setting of the adjustment bits may be performed dynamically or statically. Dynamically, a system with USB circuits may measure the rise time and fall time for a given USB connection and issue updated adjustment bits to circuit 100. These may be issued by, for example, commands writing values to registers. The adjustment may be in response to, for example, an attachment of a USB element to the connection. The cable for the attachment may cause mismatched rise and fall time. Thus, in one embodiment a measurement of rise and fall time and subsequent adjustment may be performed upon attachment of a USB element to a connection. The measurement may be made using any suitable combination of analog and digital circuitry. The adjustment to be selected may be calculated through, for example, analog and digital circuitry, a look-up table or instructions for execution by a processor. Statically, a system with USB circuits may be measured during manufacture, test, or validation of the system. The adjustment values may be written once for the lifetime of the USB circuit.

FIG. 2 is an illustration of a circuit 200 for implementing control of a DM and DP pin for a USB connection, according to embodiments of the present disclosure. The circuit may include two instances of circuit 100-100A and 100B. Circuit 200 may include a current bias source 202 (I_ref_bias) for reference. Current bias source 202 may provide a constant reference current that is independent of temperature changes and may be used by other current sources that are adjustable.

Circuit 100A may be applied to a DP pin 106A of the USB connection. In circuit 100A, a capacitor may be attached between DP pin 106A and ground. The switches of circuit 100A may be set so that RTCCC 104A may be applied to the gate of the top transistor of driver 108A. Current bias source 202 may be the original source current that is used to generate other current sources inside RTCCC 104/FTCCC 102. These other current sources within RTCCC 104/FTCCC 102 may be current mirrors (102B/C, 104A/C), while current bias source 202 is the source of current to such current mirrors. RTCCC 104A may be adjusted by trim bits such that its current may be increased, decreased, or maintained by a factor of A2. The value of (1-A2) may correspond to a value, for example, in Table 1. Furthermore, the value of the voltage between the top of driver 108A and the gate of the first transistor of driver 108A may be equal to (A2*Cgs), wherein Cgs is the capacitance between the source and gate of the first transistor of driver 108A.

Circuit 100B may be applied to a DM pin 106B of the USB connection. In circuit 100B, a capacitor may be attached between DM pin 106B and ground. The switches of circuit 100B may be set so that FTCCC 104B may be applied to the gate of the bottom transistor of driver 108B. FTCCC 104B may be adjusted by trim bits such that its current may be increased, decreased, or maintained by a factor of A1. The value of (1-A1) may correspond to a value, for example, in Table 1. Furthermore, the value of the voltage between ground and the gate of the second transistor of driver 108B may be equal to (A1*Cgs), wherein Cgs is the capacitance between the source and gate of the second transistor of driver 108B.

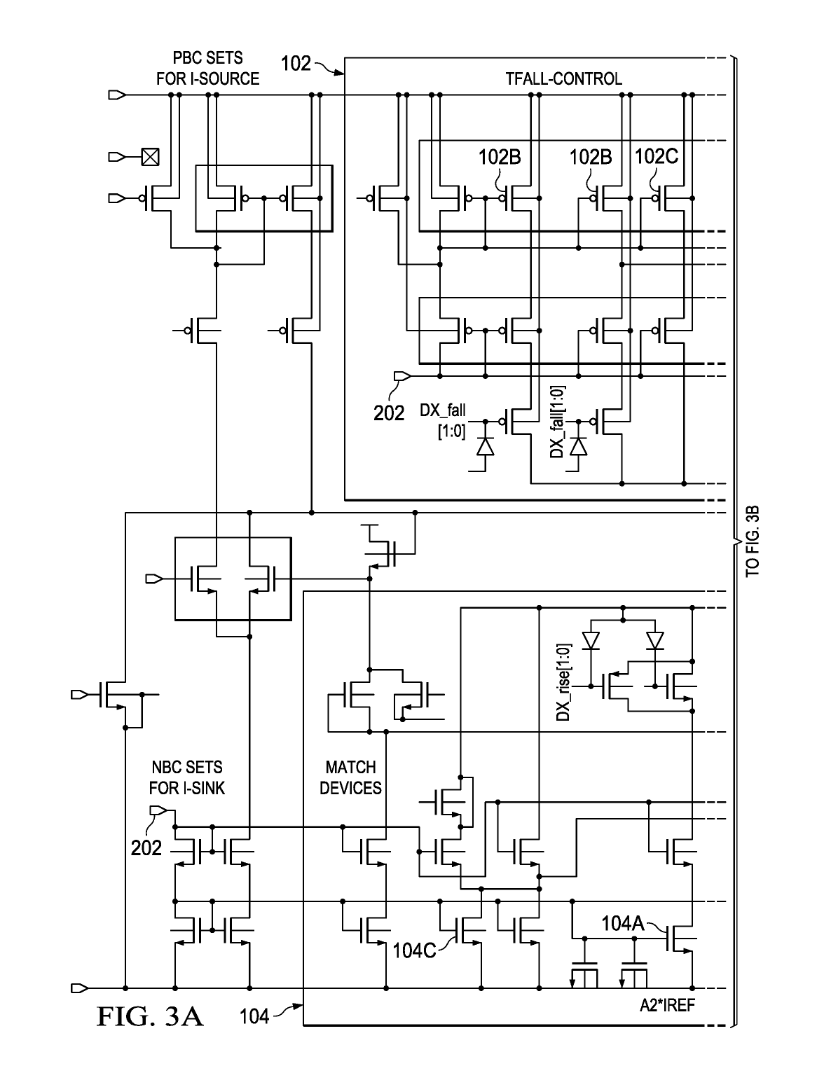

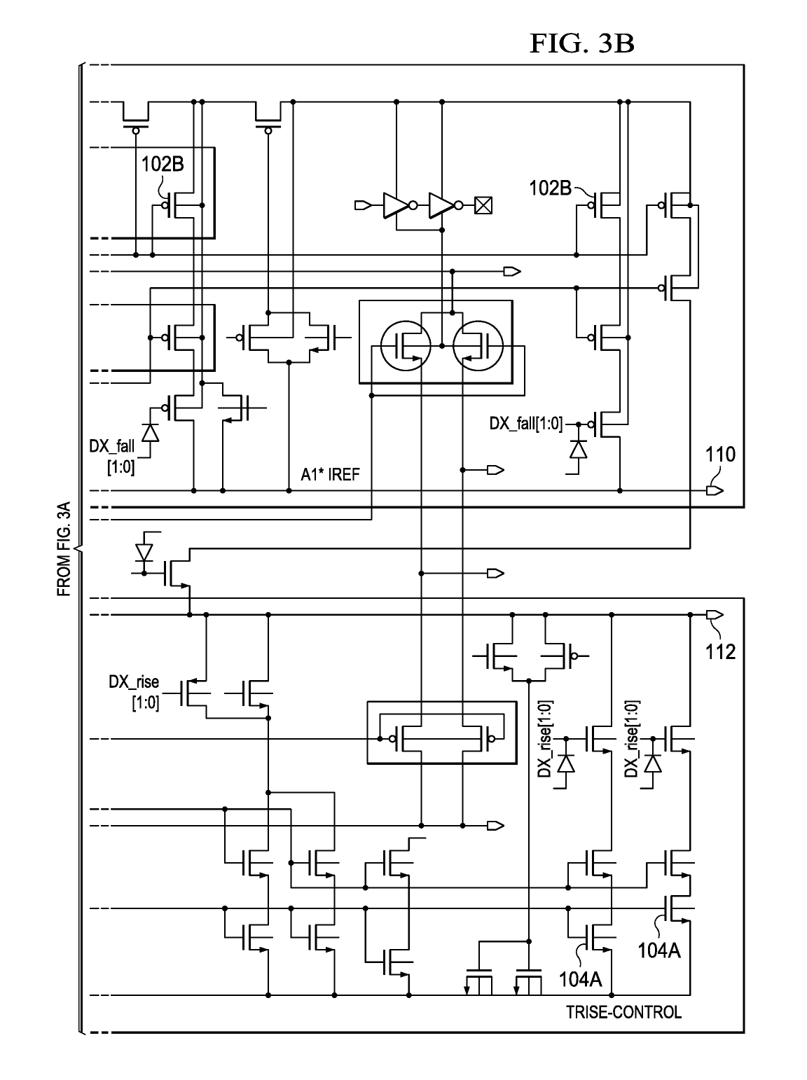

FIGS. 3A and 3B are a more detailed illustration of a schematic implementing circuit 100, according to embodiments of the present disclosure. Fall time control current 102 (B/C), control bits associated with fall time control current 102, rise time control current 104 (A/C), control bits associated with rise time control current 104, driver 108 (A/B), and I_ref_bias 202 are shown.

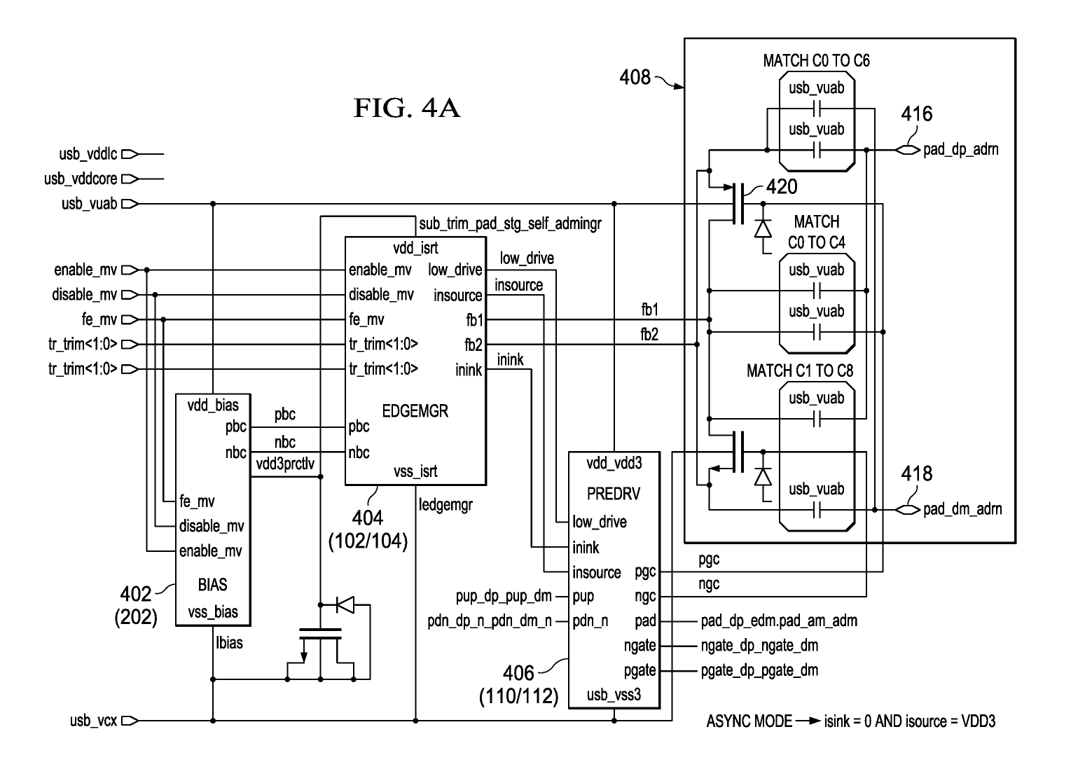

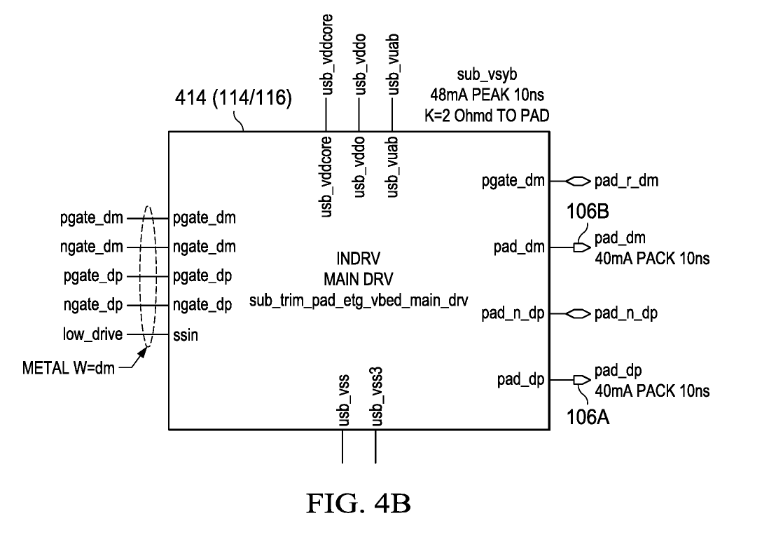

FIGS. 4A and 4B are an illustration of another, more detailed schematic for implementing circuit 100, according to embodiments of the present disclosure. DP pin 106A, DM pin 106B, and switches 110/112 are shown.

As shown in FIGS. 4A and 4B, a bias current circuit 402 may implement a current source to implement, fully or in-part, I_ref_bias 202. Bias current circuit 402 may provide a constant reference current independent of temperature changes or other interference.

A manager circuit 404 (edgemgr) may be configured to adjust current sources as applied to drivers in implementations of circuit 100. Manager circuit 404 may read adjustment bits, or may receive adjustment bits in a command, and may cause the associated changes in rise or fall time through current skewing to the gates of transistors in implementations of driver 108. Manager circuit 404 may implement elements 102 and 104.

A switching circuit 406 (predrv) may be configured to provide switching between current sources and driver circuit 420. The switching may apply current sufficient to make the rise and fall of signals on DM pin 418 and DP pin 416. Switching circuit 406 may implement elements 110 and 112.

Match circuit 408 may be configured to charage a parasitic capacitor due to bond pad and electrostatic discharge elements needed to implement circuit 100.

Circuit 414 is a representation of circuit 100 as implemented in a suitable package or other semiconductor device. Inputs and outputs are shown, and circuit 414 may be implemented within a larger USB circuit and may control the rise and fall of signals across the DM and DP pins therein.

The present disclosure has been described in terms of one or more embodiments, and it should be appreciated that many equivalents, alternatives, variations, and modifications, aside from those expressly stated, are possible and within the scope of the disclosure. While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein.

We claim:

1. An apparatus, comprising:
a first output pin;
a first output driver circuit communicatively coupled to the first output pin and configured to output a rising signal or falling signal on the first output pin; and
a first programmable current source communicatively coupled to the first output driver circuit and configured to:
drive a speed of a rising signal or of a falling signal on the first output pin; and
based upon first adjustment data, increase or decrease current to the first output driver circuit to change the speed of the rising signal or of the falling signal on the first output pin.

2. The apparatus of claim 1, further comprising:
a second output pin;
a second output driver circuit communicatively coupled to the second output pin and configured to output a rising signal or falling signal on the second output pin; and
a second programmable current source communicatively coupled to the second output driver circuit and configured to:
drive a speed of a rising signal or of a falling signal on the second output pin; and
based upon second adjustment data, increase or decrease current to the second output driver circuit to change the speed of the rising signal or of the falling signal on the second output pin.

3. The apparatus of claim 2, wherein:
the first output pin is a DM pin of a universal serial bus (USB) connection; and
the second output pin is a DP pin of the USB connection.

4. The apparatus of claim 1, further comprising a second programmable current source communicatively coupled to the first output driver circuit and configured to:
drive a speed of the rising signal on the first output pin; and
based upon second adjustment data, increase or decrease current to the first output driver circuit to change a speed of the rising signal;
wherein the first programmable current source is further configured to drive the speed of the falling signal on the first output pin.

5. The apparatus of claim 1, wherein the first programmable current source is configured to use the first adjustment data to increase or decrease current to the first output driver circuit in order to more closely match a speed of a rising signal or of a falling signal on a second output pin.

6. The apparatus of claim 1, wherein the first adjustment data includes information of a relative increase or decrease of the speed of a rising signal or of a falling signal.

7. The apparatus of claim 1, wherein the first programmable current source is configured to increase or decrease current to the first output driver circuit to change the speed of the rising signal or of the falling signal on the first output pin in response to a change in a load on the first output pin.

8. A system, comprising:
a first output pin;
a second output pin;
a first output driver circuit communicatively coupled to the first output pin and configured to output a rising signal or falling signal on the first output pin; and
a first programmable current source communicatively coupled to the first output driver circuit and configured to:
drive a speed of a rising signal or of a falling signal on the first output pin; and
based upon first adjustment data, increase or decrease current to the first output driver circuit to change the speed of the rising signal or of the falling signal on the first output pin.

9. The system of claim 8, further comprising:
a second output driver circuit communicatively coupled to the second output pin and configured to output a rising signal or falling signal on the second output pin; and
a second programmable current source communicatively coupled to the second output driver circuit and configured to:
drive a speed of a rising signal or of a falling signal on the second output pin; and
based upon second adjustment data, increase or decrease current to the second output driver circuit to change the speed of the rising signal or of the falling signal on the second output pin.

10. The system of claim 9, wherein:
the first output pin is a DM pin of a universal serial bus (USB connection; and
the second output pin is a DP pin of the USB connection.

11. The system of claim 8, further comprising a second programmable current source communicatively coupled to the first output driver circuit and configured to:
drive a speed of the rising signal on the first output pin; and
based upon second adjustment data, increase or decrease current to the first output driver circuit to change a speed of the rising signal;
wherein the first programmable current source is further configured to drive the speed of the falling signal on the first output pin.

12. The system of claim 8, wherein the first programmable current source is configured to use the first adjustment data to increase or decrease current to the first output driver circuit in order to more closely match a speed of a rising signal or of a falling signal on the second output pin.

13. The system of claim 8, wherein the first adjustment data includes information of a relative increase or decrease of the speed of a rising signal or of a falling signal.

14. The system of claim 8, wherein the first programmable current source is configured to increase or decrease current to the first output driver circuit to change the speed of the rising signal or of the falling signal on the first output pin in response to a change in a load on the first output pin.

15. A method of operating a system for matching slew rates of a connection, the connection comprising a first output pin and a second output pin, the method comprising:
providing current from a first programmable current source to output a rising signal or falling signal on the first output pin;
driving a speed of the rising signal or of the falling signal on the first output pin; and
based upon first adjustment data, increasing or decreasing current to change the speed of the rising signal or of the falling signal on the first output pin.

16. The method of claim 15, further comprising:
providing current from a second programmable current source to output a rising signal or falling signal on the second output pin;
driving a speed of a rising signal or of a falling signal on the second output pin; and
based upon second adjustment data, increasing or decreasing current to change the speed of the rising signal or of the falling signal on the second output pin.

17. The method of claim 16, wherein:
the first output pin is a DM pin of a universal serial bus (USB connection; and
the second output pin is a DP pin of the USB connection.

18. The method of claim 15, further comprising:
providing current from a second programmable current source to output a rising signal or falling signal on the first output pin; and
based upon second adjustment data, increasing or decreasing current to change a speed of the rising signal;
wherein the first programmable current source is further configured to drive the speed of the falling signal on the first output pin.

19. The method of claim 15, further comprising using the first adjustment data to increase or decrease current in order to more closely match a speed of a rising signal or of a falling signal on the second output pin.

20. The method of claim 15, further comprising increasing or decreasing current to change the speed of the rising signal or of the falling signal on the first output pin in response to a change in a load on the first output pin.
